(19) United States
(12) Patent Application Publication
(10) Pub. No.: US 2009/0008776 A1
(43) Pub. Date: Jan. 8, 2009

(54) Electronic Component Mounted Body, Electronic Component with Solder Bump, Solder Resin Mixed Material, Electronic Component Mounting Method and Electronic Component Manufacturing Method

(76) Inventors: Takashi Kitae, Osaka (JP); Seiichi Nakatani, Osaka (JP); Seiji Karashima, Osaka (JP); Susumu Sawada, Osaka (JP); Kenichi Hotehama, Osaka (JP)

Correspondence Address: MCDERMOTT WILL & EMERY LLP, 600 13TH STREET, NW, WASHINGTON, DC, 20005-3096, US

(21) Appl. No.: 12/281,195

(22) PCT Filed: Feb. 23, 2007
(86) PCT No.: PCT/JP2007/053357

§ 371 Date: Aug. 29, 2008

(30) Foreign Application Priority Data
Mar. 3, 2006 (JP) 2006-057646

(51) Int. Cl. H01L 23/488; H05K 3/30; H05K 1/02; H01L 21/56

(52) U.S. Cl. 257/737; 29/840; 438/127; 174/258

(57) ABSTRACT

In an electronic component mounted body, an electrode of a first electronic component and an electrode of a second electronic component are electrically connected by a solder connecter, and the solder connecter contains solder and insulation filler. Alternatively, a solder bump is formed on the electrode of the electronic component, and the solder bump includes the insulation filler.

### FIELD OF THE INVENTION

The present invention relates to an electronic component mounted body including an electronic component provided with solder bumps, and a solder resin mixed material used for the electronic component mounted body.

### BACKGROUND OF THE INVENTION

In order to respond to a recent demand for a higher density and a higher integration in a semiconductor integrated circuit (LSI) used for an electronic device, electrodes in an LSI chip each having a larger number of pins and narrower pitches are rapidly being developed. When LSI chips are mounted on a circuit substrate, flip-chip mounting is often adopted in order to lessen wiring delays. A conventional method of the flip-chip mounting is such that solder bumps are formed on electrodes of the LSI chip, and the electrodes of the LSI chips are bonded, like a single unit, with electrodes formed on the circuit substrate via the solder bumps.

In order to mount a next-generation LSI having more than 5,000 electrodes on the circuit substrate, however, it is necessary to form bumps corresponding to such narrow pitches as at most 100 μm, but it is difficult to meet such requirement using the currently available solder bump formation technologies. Further, it is necessary to form a large number of bumps corresponding to the number of electrodes, which makes it necessary to reduce a mounting tact per chip in order to achieve the cost reduction.

The conventional examples of the bump formation technology are the plating method, screen printing method and the like. The plating method is suitable for narrow pitches, however, disadvantageous in its complicated steps and productivity. The screen printing method is superior in its productivity, however, is not suitable for narrowing pitches because a mask is used therein.

In order to cope with these disadvantages, some technologies for selectively forming solder bumps on electrodes of an LSI chip or a circuit substrate were recently introduced. These technologies, which are not only suitable for the formation of minute bumps but also superior in productivity because the bumps can be formed by one operation, are attracting attention with the expectation that they can be suitably adopted when the next-generation LSIs are mounted on the circuit substrate.

One of these technologies is called the solder pasting method (for example, see the Patent Document 1). According to the technology, solder paste, in which metallic particles and flux are mixed, is solidly spread on to a surface of a substrate on which electrodes are formed, the substrate is heated so that the metallic particles are melted, and solder bumps are selectively formed on the electrodes which are highly wettable.

According to another technology called the super solder method (for example, see the Patent Document 2), a paste-like composition including organic acid lead salt and metallic tin as its main constituents (chemical reaction deposited solder) is solidely spread onto a surface of a substrate on which electrodes are formed, and the substrate is heated so as to generate a substitution reaction between Pb and Sn, and Pb/Sn alloy is selectively deposited on the electrodes.

In the solder pasting method and the super solder method wherein a paste-like composition is spread onto the substrate, however, variation in thicknesses and concentrations occurs locally. As a result, an amount of the deposited solder is different in each of the electrodes, which makes it not possible to obtain bumps having an even height. Further, according to these methods wherein the paste-like composition is applied onto the circuit substrate which is not flat due to the electrodes formed thereon, the electrodes, which constitute protrusions, cannot be supplied with an enough amount of solder, and it is thereby difficult to obtain dumps having a desirable height required in the flip-chip mounting.

Further, the flip-chip mounting, wherein the conventional bump formation technology is adopted, further requires a step of injecting resin called under-fill into between the semiconductor chip and the circuit substrate in order to fix the semiconductor chip to the circuit substrate after the semiconductor chip is mounted on the circuit substrate provided with the bumps thereon.

Accordingly, the flip-chip mounting technology using an anisotropic conductive material (for example, see the Patent Document 3) was developed as a method of simultaneously realizing two operations: the electrical connection between the electrodes of the semiconductor chip and the circuit substrate facing each other; and the fixation of the semiconductor chip to the circuit substrate. According to the technology, thermosetting resin including conductive particles is supplied to between the semiconductor chip and the circuit substrate, and the semiconductor chip is pressurized and the thermosetting resin is heated at the same time. Thus, the electrodes of the semiconductor chip and the circuit substrate can be electrically connected to each other, and the semiconductor chip can be fixed to the circuit substrate at the same time. The flip-chip mounting technology using the anisotropic conductive material is applicable not only to the electrical connection between the semiconductor chip and the circuit substrate but also to the connection between two circuit substrates.
Patent Document 1: 2000-94179 of the Japanese Patent Applications Laid-Open
Patent Document 2: H1-157796 of the Japanese Patent Applications Laid-Open
Patent Document 3: 2000-332055 of the Japanese Patent Applications Laid-Open
Patent Document 4: 2004-260131 of the Japanese Patent Applications Laid-Open
Non-Patent Document 1: 10th Symposium on “Micro joining and Assembly Technology in Electronics” Feb. 5-6, 2004, pp. 183-188
Non-Patent Document 2: 9h Symposium on “Micro joining and Assembly Technology in Electronics” Feb. 6-7, 2003, pp. 115-120

### DISCLOSURE OF THE INVENTION

### Problems to be Solved by the Invention

In the flip-chip mounting and the inter-substrate connection wherein the anisotropic conductive material is used as described earlier, however, the electrical conduction between the electrodes is obtained by the mechanical contact via the conductive particles, which makes it difficult to stabilize the conduction.

Further, the conductive particles sandwiched by the electrodes facing each other are retained by the cohesion of the resin generated when thermally cured. Therefore, it is necessary to control the coefficient of elasticity and the coefficient of thermal expansion of the thermosetting resin and the distribution of particle diameters of the conducive particles.

Therefore, the flip-chip mounting technology using the anisotropic conductive material still includes a number of issues to be solved in terms of productivity and reliability when the technology is applied to the next-generation LSI chips each having more than 5,000 electrodes. There a real so a number of similar issues to be solved in the technology when used for the inter-substrate connection for which narrow pitches, connection of a large number of pins and a high reliability are now demanded.

### Means for Solving the Problem

The present invention was made in order to solve the problems thus described, and a main object thereof is to provide an electronic component mounted body which is reliably applicable to the flip-chip mounting for the next-generation LSIs and the inter-substrate connection.

An electronic component mounted body according to the present invention comprises

a first electronic component provided with a plurality of electrodes;

a second electronic component provided with a plurality of electrodes and facing the first electronic component in a state where the electrodes thereof face the electrodes of the first electronic component; and

solder connecters provided between the electrodes of the first electronic component and the electrodes of the second electronic component so as to electrically connect the electrodes of the first and second electronic component to each other, wherein the solder connecters include insulation filler.

Another electronic component mounted body according to the present invention comprises a first electronic component provided with a plurality of electrodes;

a second electronic component provided with a plurality of electrodes and facing the first electronic component in a state where the electrodes thereof face the electrodes of the first electronic component;

solder connecters provided between the electrodes of the first electronic component and the electrodes of the second electronic component so as to electrically connect the electrodes of the first and second electronic component to each other; and

a resin mixture provided between the first and second electronic components so as to bond the first and second electronic component, wherein the solder connecters and the resin mixture include insulation filler of the same constitution.

An electronic component provided with solder bumps according to the present invention comprises

a plurality of electrodes; and

solder bumps provided in the electrodes, wherein the solder bumps include insulation filler.

A solder resin mixture according to the present invention is a solder resin mixture including resin, solder powder and insulation filler, wherein the insulation filler is surface-processed in order to improve wettability thereof relative to the solder which is melted.

An electronic component mounting method according to the present invention is a method of mounting an electronic component wherein a first electronic component provided with a plurality of electrodes and a second electronic component provided with a plurality of electrodes are placed so that the electrodes of the respective electronic components face each other, and the electrodes of the first and second electronic components facing each other are electrically connected to each other via solder, including:

a first step in which a solder resin mixture including resin, solder powder and insulation filler is supplied to a surface of the first electronic component on which the electrodes are formed;

a second step in which the second electronic component is placed so as to face the first electronic component in the state where the electrodes of the respective electronic components face each other;

a third step in which the solder resin mixture is heated; and

a fourth step in which solder connecters are formed when the solder powder included in the solder resin mixture is self-assembled on the electrodes of the first and second electronic components so that the electrodes of the respective electronic components are electrically connected to each other, wherein

at least a part of the insulation filler is included in the solder connecters when the solder powder is self-assembled in the fourth step.

An electronic component manufacturing method according to the present invention is a method of manufacturing an electronic component wherein solder bumps are formed on a plurality of electrodes provided therein, including:

a first step in which a solder resin mixture including resin, solder powder and insulation filler is supplied to the electronic component; and

a second step in which the solder resin mixture is heated;

a third step in which the solder powder included in the solder resin mixture is self-assembled on the electrodes so that the solder bumps are formed on the electrodes, wherein

at least a part of the insulation filler is included in the solder connecters when the solder powder is self-assembled in the third step.

### EFFECT OF THE INVENTION

In the electronic component mounted body and the electronic component provided with the solder bumps according to the present invention, wherein the insulation filler having a small coefficient of thermal expansion is included in the solder connecters and the solder bumps, the reliability of the connection can be improved without the loss of the electrical characteristics.

According to the electronic component mounting method and the electronic component manufacturing method of the present invention, the insulation filler can be included in the solder connecters and the solder bumps as soon as they are formed. As a result, the electronic component can be manufactured with a shorter tact, which improves the productivity.

### BRIEF DESCRIPTION OF THE DRAWINGS

FIG. 1A is a process sectional view which illustrates a first state in an electronic component mounting method according to a preferred embodiment 1 of the present invention.

FIG. 1B is a process sectional view which illustrates a second state in the electronic component mounting method according to the preferred embodiment 1.

FIG. 1C is a process sectional view which illustrates a third state in the electronic component mounting method according to the preferred embodiment 1.

FIG. 2A is a process sectional view which illustrates a first state in a mounting method wherein an air bubble generating agent is included in a solder resin mixture, which is the electronic component mounting method according to the preferred embodiment 1.

FIG. 2B is a process sectional view which illustrates a second state in the mounting method wherein the air bubble generating agent is included in the solder resin mixture, which is the electronic component mounting method according to the preferred embodiment 1.

FIG. 2C is a process sectional view which illustrates a third state in the mounting method wherein the air bubble generating agent is included in the solder resin mixture, which is the electronic component mounting method according to the preferred embodiment 1.

FIG. 2D is a process sectional view which illustrates a fourth state in the mounting method wherein the air bubble generating agent is included in the solder resin mixtures which is the electronic component mounting method according to the preferred embodiment 1.

FIG. 3A is a process sectional view which illustrates a first state in a mounting method wherein a washing step is included, which is the electronic component mounting method according to the preferred embodiment 1.

FIG. 3B is a process sectional view which illustrates a second state in the mounting method wherein the washing step is included, which is the electronic component mounting method according to the preferred embodiment 1.

FIG. 3C is a process sectional view which illustrates a third state in the mounting method wherein the washing step is included, which is the electronic component mounting method according to the preferred embodiment 1.

FIG. 3D is a process sectional view which illustrates a fourth state in the mounting method wherein the washing step is included, which is the electronic component mounting method according to the preferred embodiment 1.

FIG. 4A is a process sectional view which illustrates a first state in a solder-bump-attached electronic component mounting method according to a preferred embodiment 2 of the present invention.

FIG. 4B is a process sectional view which illustrates a second state in the solder-bump-attached electronic component mounting method according to the preferred embodiment 2.

FIG. 4C is a process sectional view which illustrates a third state in the solder-bump-attached electronic component mounting method according to the preferred embodiment 2.

FIG. 5A is a process sectional view which illustrates a first state in a mounting method wherein an air bubble generating agent is included in a solder resin mixture, which is the solder-bump-attached electronic component mounting method according to the preferred embodiment 2.

FIG. 5B is a process sectional view which illustrates a second state in the mounting method wherein the air bubble generating agent is included in the solder resin mixture, which is the solder-bump-attached electronic component mounting method according to the preferred embodiment 2.

FIG. 5C is a process sectional view which illustrates a third state in the mounting method wherein the air bubble generating agent is included in the solder resin mixture, which is the solder-bump-attached electronic component mounting method according to the preferred embodiment 2.

FIG. 5D is a process sectional view which illustrates a fourth state in the mounting method wherein the air bubble generating agent is included in the solder resin mixture, which is the solder-bump-attached electronic component mounting method according to the preferred embodiment 2.

FIG. 5E is a process sectional view which illustrates a fifth state in the mounting method wherein the air bubble generating agent is included in the solder resin mixture, which is the solder-bump-attached electronic component mounting method according to the preferred embodiment 2.

FIG. 6A is a process sectional view which illustrates a first state in an electronic component mounted body manufacturing method according to the preferred embodiment 2.

FIG. 6B is a process sectional view which illustrates a second state in the electronic component mounted body manufacturing method according to the preferred embodiment 2.

FIG. 6C is a process sectional view which illustrates a third state in the electronic component mounted body manufacturing method according to the preferred embodiment 2.

FIG. 7A is a process sectional view which illustrates a first state in a manufacturing method of a solder-bump-attached electronic component and an electronic component mounted body, wherein solder balls are used as a comparative example.

FIG. 7B is a process sectional view which illustrates a second state in the manufacturing method of the solder-bump-attached electronic component and the electronic component mounted body, wherein the solder balls are used as the comparative example.

FIG. 7C is a process sectional view which illustrates a third state in the manufacturing method of the solder-bump-attached electronic component and the electronic component mounted body, wherein the solder balls are used as the comparative example.

FIG. 7D is a process sectional view which illustrates a fourth state in the manufacturing method of the solder-bump-attached electronic component and the electronic component mounted body, wherein the solder balls are used as the comparative example.

### DESCRIPTION OF REFERENCE SYMBOLS

1 first electronic component
2 second electronic component
3 solder resin mixture
4 solder powder
5 insulation filler
6 electrode
7 resin
8 solder connecter
9 solder bump
10 air bubble
11 resin mixture
12 flat plate
13 solder ball

### PREFERRED EMBODIMENTS OF THE INVENTION

Hereinafter, preferred embodiments of the present invention are described referring to the drawings. In the drawings described below, components having substantively the same function are illustrated with the same reference symbols in order to simplify the description. The present invention is not necessarily limited to the embodiments described below.

### Preferred Embodiment 1

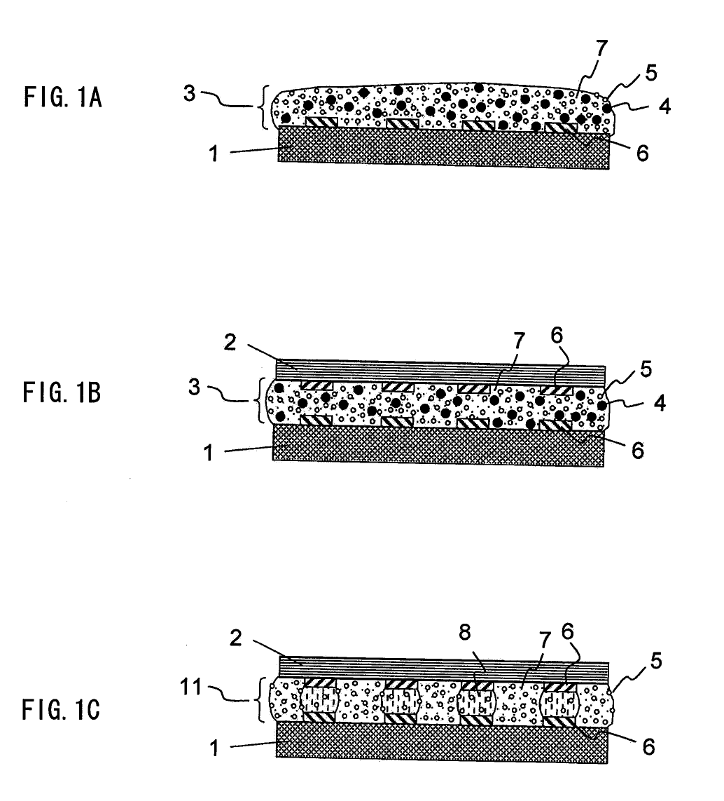

FIGS. 1A-1C illustrate an electronic component mounting method according to a preferred embodiment 1 of the present invention.

As shown in FIG. 1A, solder resin mixture 3 including resin 7, solder powder 4 and insulation filler 5 is supplied to a surface of a first electronic component 1 on which a plurality of electrodes 6 are formed. The insulation filler 5 is not meltingly mixed with solder which is a material of the solder powder 4.

Then, as shown in FIG. 1B, a second electronic component 2 provided with a plurality of electrodes 6 is mounted at a determined position on the surface of the first electronic component 1 provided with the electrodes so that the electrodes 6 of the first electronic component 1 and the electrodes 6 of the section electronic component 2 face each other. In this state, the solder resin mixture 3 is heated at a temperature higher than a melting point of the solder.

When the solder resin mixture 3 is heated, the solder powder 4 is self-assembled on the electrodes 6, and solder connecters 8 are thereby formed. In the formation, the insulation filler 5 in the solder resin mixture 3 is simultaneously included in the solder connecters 8. As a result, an electronic component mounted body having a structure shown in FIG. 1C, in which the electrodes 6 of the first electronic component 1 and the electrodes 6 of the second electronic component 2 are electrically connected to each other, is obtained.

In the self-assembly of the solder powder, the solder powder 4 may be assembled on the electrodes 6 and 6 of the electronic components 1 and 2 by utilizing a difference between the wettability of the solder powder 4 relative to the electrodes 6 and 6 and the wettability of the solder powder 6 relative to the surfaces of the electronic components 1 where the electrodes are not provided. Preferably, the solder powder 4 is self-assembled on the electrodes 6 and 6 of the electronic components 1 and 2 by an effect obtained by an air bubble generating agent added to the solder resin mixture in advance.

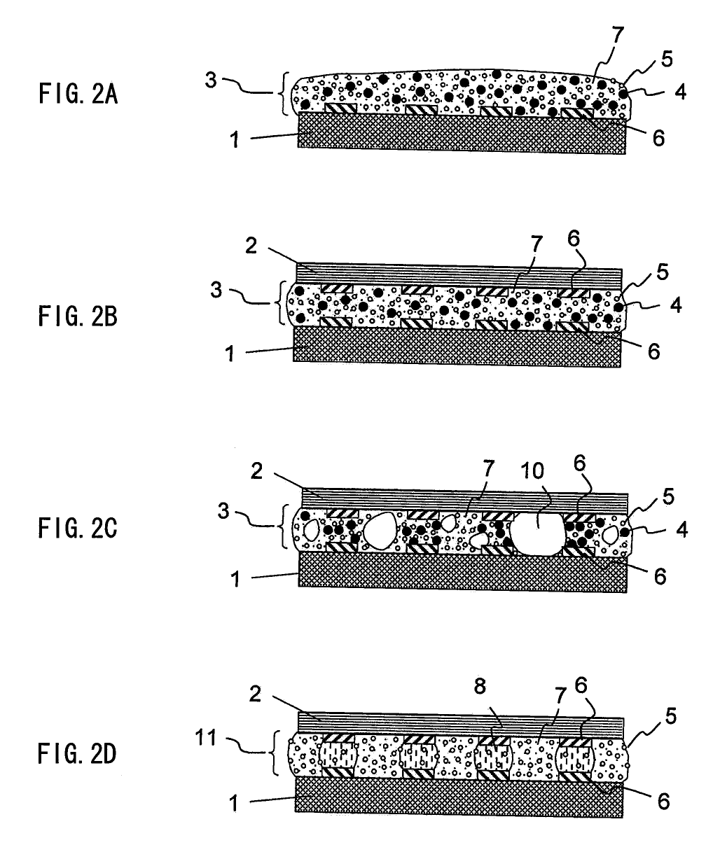

The Applicant of the present invention examined the flip-chip mounting method and the solder bump formation method applicable to the next-generation LSI chip, and proposed a novel method wherein the electrodes can be evenly connected to each other by means of the air bubble generating agent. In the method, the air bubble generating agent is included in the solder resin mixture 3 before the mounting. Below is described an example of an electronic component manufacturing method according to the preferred embodiment 1 in which the air bubble generating agent is used referring to FIGS. 2A-2D.

The air bubble generating agent (not shown) is included in the solder resin mixture 3, and the resulting solder resin mixture 3 is applied onto the surface of the first electronic component 1 on which the electrodes are formed (see FIG. 2A). The second electronic component 2 is placed on a determined position on the surface of the first electronic component 1 on which the electrodes are formed (see FIG. 2B), and then, the solder resin mixture 3 is heated up to at least a temperature at which air bubbles are generated from the air bubble generating agent. As a result of the heating process, air bubbles 10 are generated from the air bubble generating agent and grow bigger (see FIG. 2C). Most of the bubbles 10 selectively grow bigger at flat sections on the electrode-formed surfaces of the two components 1 and 2 (sections where the electrodes are not formed) by the surface tension of the resin. At the same time, the resin 7 and the solder powder 4 and the insulation filler 5 included in the resin 7, which are more possibly present on the electrodes 6 by the surface tension of the resin 7, are self-assembled on the electrodes 6. The resin, solder powder and insulation filler move due to the generated air bubbles, and are thereby self-assembled on the electrodes. Finally, the solder powder 4 wettingly extends on the plurality of electrodes 6 and 6, and the solder connecters 8 which electrically connects the electrodes 6 and 6 are formed by the solder powder 4 which thus wettingly extends. At the time, the solder connecters 8 are formed with the insulation filler 5 in the resin 7 being included therein (see FIG. 2D). Some of the insulation filler 5 assembled on the electrodes 6 may not be included because it is pushed out of areas of the electrodes when the solder powder 4 wettingly extends onto the electrodes 6. In other words, all of the insulation filler assembled on the electrodes 6 does not need to be included, but only some of it need to be included. Referring to a piece of insulation filler, for example, the whole of it may be included in the solder connecter, or at least a part of it may be embedded in the solder connecter. When the solder powder is thus self-assembled, the solder powder and the insulation filler is assembled on the electrodes together with the resin, and the solder powder thereby wettingly spreads. As a result, more of the insulation filler can be easily included in the solder connecters 8 when the solder connecters 8 are formed.

The solder connecters 8 may be formed in such a way that the solder powder 4 is self-assembled using the wettability of the melted solder powder 4. In that case, solder resin mixture not including the air bubble generating agent may be used.

Describing the self-assembly of the solder powder 4, the solder resin mixture 3 in which the solder powder 4 is evenly dispersed in the resin 7 is uniformly applied onto a surface including the sections where the solder connecters 8 are desirably formed, and the surface is subjected to a predetermined process such as heating. The self-assembly of the solder powder 4 is not necessarily limited to the foregoing manner, and any manner may be adopted as far as the solder connecters 8 are selectively formed at the desirable electrodes 6. More specifically, the self-assembly denotes a state where the probability that the solder powder, insulation filler and resin are present on the electrodes is high because they move as the air bubble generating agent is boiled and the air bubbles are thereby generated. The self-assembly is nothing to do with whether the solder powder is melted or not. In the case where the solder powder is melted, the solder powder, while being self-assembled and incorporating the insulation filler, wettingly spreads onto the electrodes. In the case where the solder powder is not melted, the solder powder wettingly spreads onto the electrodes while incorporating the insulation filler after the heating temperature is set to at least the melting temperature when the solder powder is self-assembled.

In the conventional mounting method wherein solder balls are mounted on the electrodes of the electronic component, it is not possible for the solder balls to include the insulation filler. In the mounting method according to the present invention wherein the solder powder is self-assembled, the insulation filler 5 is included in the solder resin mixture 3. As a result, the structure wherein the solder connecters 8 are formed and the insulation filler 5 is incorporated therein can be easily obtained. Accordingly, the mechanical strength of the electronic components can be significantly improved.

An average particle diameter of the insulation filler 5 is preferably smaller than an average particle diameter of the solder powder 4 included in the solder resin mixture 3 because the insulation filler 5 can be accordingly more easily incorporated in the solder connecters 8. This is because when the particle diameters of the solder powder are increased, an oxide coating film is thinner, which helps the solder powder easily wettingly extend on the electrodes, and the insulation filler 5 can be thereby more easily included in the solder connecters 8. Further, in the case where the particle diameters of the solder powder are larger than the particle diameters of the insulation filler, the solder powder 4 easily wettingly spreads onto the electrodes 6 so as to cover the insulation filler. As a result, the insulation filler can be easily incorporated in the solder connecters.

The average particle diameter of the insulation filler 5 is preferably smaller than an interval between the electrode 6 of the first electronic component 1 and the electrode 6 of the first electronic component because the insulation filler 5 can be easily included in the solder connecter 8 when the particle diameters of the insulation filler 5 are smaller than the interval between the electrodes 6.

After the solder powder 4 is thus self-assembled and the solder connecters 8 are formed, the resin 7 is preferably solidified so that the first electronic component 1 and the second electronic component 2 are integrally fixed. For example, thermoplastic resin is used as the resin 7, and heated up to at least a softening point and then cooled down after the solder powder 4 is self-assembled. Then, the resin 7 is solidified again, and the first electronic component 1 and the second electronic component 2 can be thereby integrally fixed. Further, a curing agent is preferably added to the solder resin mixture 3, and the resin 7 is cured after the solder powder 4 is self-assembled, so that the first electronic component 1 and the second electronic component 2 are integrally fixed. In this case, the respective steps are preferably separately performed in such a way that the resin 7 and the curing agent are cured at a speed slower than a speed at which the solder powder 4 is self-assembled. Preferable examples of the curing method which can be adopted are heat curing, photo-curing and the like. Referring to the curing process, the curing process does not need to be performed in one stage, and may be performed in two stages after the stage B.

In the preferred embodiment 1, a flip-chip mounted body wherein the first electronic component 1 is a circuit substrate and the second electronic component 2 is a semiconductor is a preferable embodiment. Further, an inter-substrate connection wherein the first electronic component 1 and the second electronic component 2 are circuit substrates is also a preferable embodiment. The first electronic component 1 is not limited to the circuit substrate, and it may be any electronic component conventionally used, such as a semiconductor, a module component, a passive component, or the like. In a similar manner, the second electronic component 2 is not limited to a semiconductor or circuit substrate, and it may be any electronic component conventionally used.

It is expected that the electronic component mounted body thus manufactured with the insulation filler 5 included in the solder connecters 8 can improve the connection reliability. In general, the solder connecters 8 in the electronic component mounted body is subject to the stress generated by a difference in coefficients of thermal expansion between the members constituting the electronic component mounted body. When the stress is repeatedly applied thereto, fatigue breakdown occurs in the solder, which results in a connection failure. In the flip-chip mounted body wherein the first electronic component 1 is a circuit substrate and the second electronic component 2 is a semiconductor, for example, the coefficient of thermal expansion of Si constituting the semiconductor is a few ppms, while that of the circuit substrate formed from resin is a few-dozen ppms. Further, in the mounting body comprising a large number of members such as electrodes of the semiconductor and the circuit substrate, the stress is repeatedly applied to the solder connecters 8 by the difference in coefficients of thermal expansion between the members due to heat resulting from the usage environment and the semiconductor. In the flip-chip mounted body, the semiconductor and the circuit substrate are conventionally fixed to each other with resin mixture including resin and insulation filler as an effort for scattering the stress applied to the solder.

In the preferred embodiment 1, wherein the insulation filler 5 is included in the solder connecters 8, the elongation percentage of the solder connecters 8 can be controlled, which improves the connection reliability. Further, the solder connecters 8 can have a shape in which the solder powder wettingly spreads because the insulation filler 5 is included therein, and the stress can be thereby scattered. In a constitution wherein only a part of the insulation filler 5 is included in the solder connecters 8 and the rest thereof is in contact with the resin 7, the insulation filler 5 has the effect in serving as a juncture between the solder connecters 8 and the resin 7. Due to these obtainable effects, the reliability of the electronic component mounted body can be improved when the insulation filler 5 is included in the solder connecters 8.

In the structure of the electronic component mounted body shown in FIGS. 1C and 2D, the insulation filler 5 included in the solder connecters 8 and the insulation filler 5 included in the resin mixture 11 are of the same constitution, in which case the mounting process can be advantageously simplified.

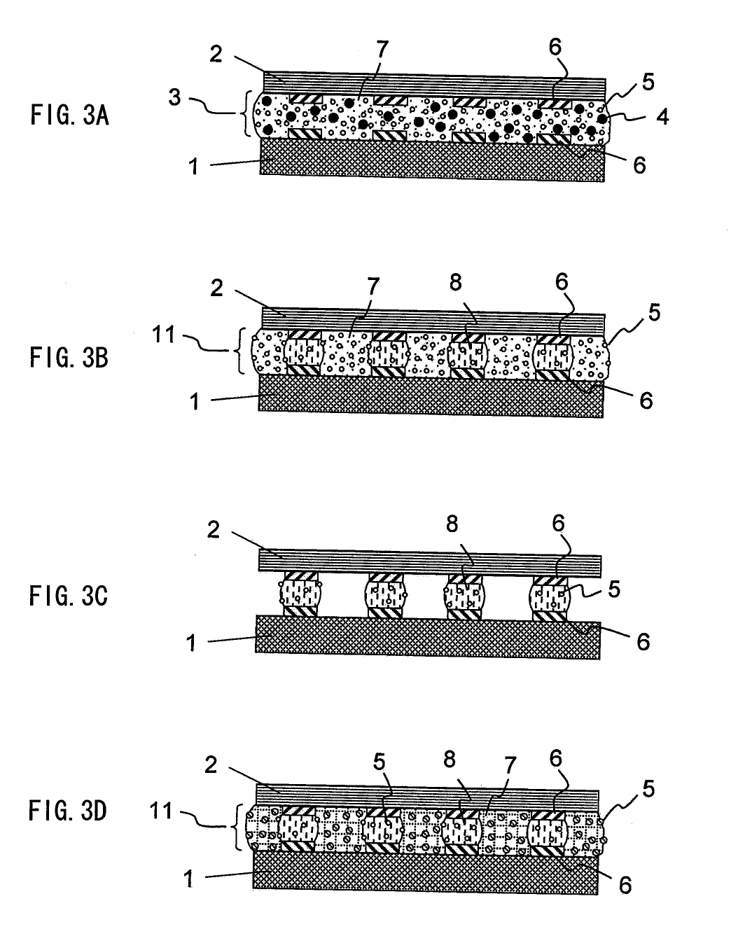

Further, as shown in FIGS. 3A-3D, the following mounting method (see FIG. 3D) is applicable: after the electronic component mounted body wherein the insulation filler 5 is included in the solder connecters 8 is manufactured (see FIG. 3B), and subsequently to a step of washing away the resin 7 and the insulation filler 5 (see FIG. 3C), a step of filling another resign mixture 11 containing the resin 7 and the insulation filler 5 is taken. In the case of the method thus constituted, solder powder having the special property of being easily self-assembled as described above is preferably used as the solder powder 4 included in the solder resin mixture 3 used in the steps shown in FIGS. 3A-3B. Further, it is preferable that the insulation filler 5 contained in the solder resin mixture 3 having special property of being easily included in the solder connecters 8 or being capable of maintaining the reliability after it is included in the solder connecters 8. Further, it is preferable that the resin mixture 11 (see FIG. 3D) to be filled in afterwards have a property suitable for integrally fixing the first and second electronic components and a favorable heat releasability.

When the insulation filler 5 is included in the solder connecters 8, all of the insulation filler 5 may be absorbed and incorporated into the solder connecters 8, or at least a part of the insulation filler 5 may be absorbed and incorporated into the solder connecters 8. In the present invention, the term “include” is used in all of these possible structures. Further, the insulation filler 5 is not necessarily included in all of the solder connecters 8, and the insulation filler 5 may be included in at least a part of the plurality of solder connecters 8 in the electronic component mounted body.

The solder powder 4 preferably does not remain in the residual resin mixture 11 in which the self-assembly of the solder powder 4 does not occur; however, a small amount of solder powder may remain therein. Even in the case where the solder powder 4 remains in the residual resin mixture 11, the present invention can be fully implemented as far as the amount of the remaining solder powder does not adversely influence the insulation reliability and the like. In the case where a step of washing off the residual resin mixture 11 (see FIG. 3C) is included after the solder powder 4 is self-assembled (see FIGS. 3A and 3B) as shown in FIGS. 3A-3D, the residual resin mixture 11 and the remaining solder powder 4 can be both removed. After the residual resin mixture 11 is washed off, the resin mixture 11 not including solder powder 11 is filled into between the first and second electronic components 1 and 2 as shown in FIG. 3D.

At least one or more types of inorganic filler selected from crystalline silica, melted silica, alumina, and alumina oxide preferably constitutes the insulation filler 5 according to the preferred embodiment 1. The shape of the filler, which may be a plate shape, a needle shape or a spherical shape, is not particularly limited. When a surface of the insulation filler 5 is modified, it can be controlled how the filler is included in the solder connecter 8. As a preferable example of the modification of the surface of the insulation filler 5, it is made possible to control the hydrophobic nature, hydrophilic nature, wettability relative to the resin, and wettability relative to the solder of the surface using a surface processing agent such as a silane coupling agent or a titanate-based coupling agent. Further, a similar effect can be exerted when a surface roughness is changed.

Preferable examples of the solder powder 4 according to the preferred embodiment 1 are conventionally used lead-containing solder such as SnPb, and lead-free solders such as SnAgCu, SnAg, SnAgBiIn, SnSb and SnBi; however, the type of the solder powder 4 is not particularly limited. Further, the average particle diameter, which is preferably approximately 1-100 μm, is not particularly limited.

Preferable examples of the resin 7 according to the preferred embodiment 1 are thermosetting resins such as epoxy resin, phenol resin, silicon resin and melamine resin; thermoplastic resins such as polyamide, polycarbonate, polyethylene telephthalate, polyphenylene sulfide; and the like; however, the type of the resin 7 is not particularly limited. Further, in the case where there is the washing step as shown in FIG. 3, silicon oil, glycerins, hydrocarbon-based oil and the like may be used in addition to the above described resin.

### Preferred Embodiment 2

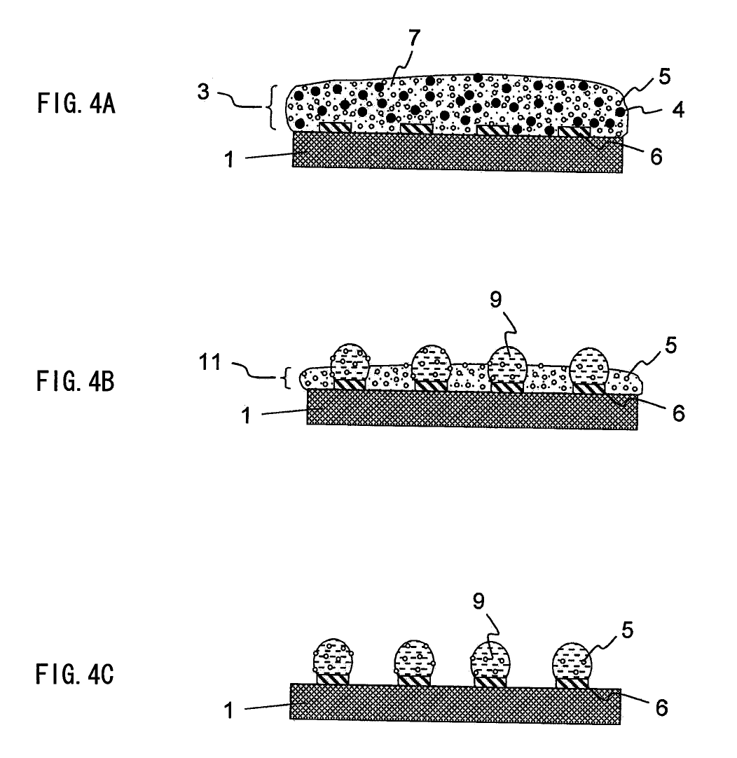

FIGS. 4A-4C illustrate a method of manufacturing an electronic component provided with solder bumps according to a preferred embodiment 2 of the present invention. The same components in the electronic component provided with solder bumps according to the present preferred embodiment as those described in the preferred embodiment 1 are shown with similar reference symbols. The present preferred embodiment is similar to the preferred embodiment 1 unless stated otherwise below, and detailed description of the similar parts is omitted.

As shown in FIG. 4A, the solder resin mixture 3 is supplied to a surface of an electronic component 1A on which a plurality of electrodes 6 are formed. The solder resin mixture 3 includes the resin 7, solder powder 4 and insulation filler 5. The insulation filler 5 is not meltingly mixed with the solder.

When the solder resin mixture 3 thus supplied is heated, the solder powder 4 is self-assembled on the electrodes 6 so that solder bumps 9 are formed as shown in FIG. 4B. At the time, the insulation filler 5 contained in the solder resin mixture 3 is simultaneously included in the solder bumps 9. A heating temperature in the final stage is higher than the melting point of the solder.

Next, as shown in FIG. 4C, the resin mixture 11 including the resin 7 and the insulation filler 5 is washed away, and the electronic component provided with the solder bumps wherein the insulation filler 5 is included in the solder bumps 9 is manufactured.

In the self-assembly of the solder powder 4, the solder powder may be assembled on the electrodes 6 of the electronic component 1A using the wettability of the melted solder powder 4 in a manner similar to the electronic component mounted body according to the preferred embodiment 1. However, a method is preferably applicable in which an air bubble generating agent is added to the solder resin mixture 3, and the solder powder is self-assembled on the electrodes 6 of the electronic component 1A by an effect thereby obtained.

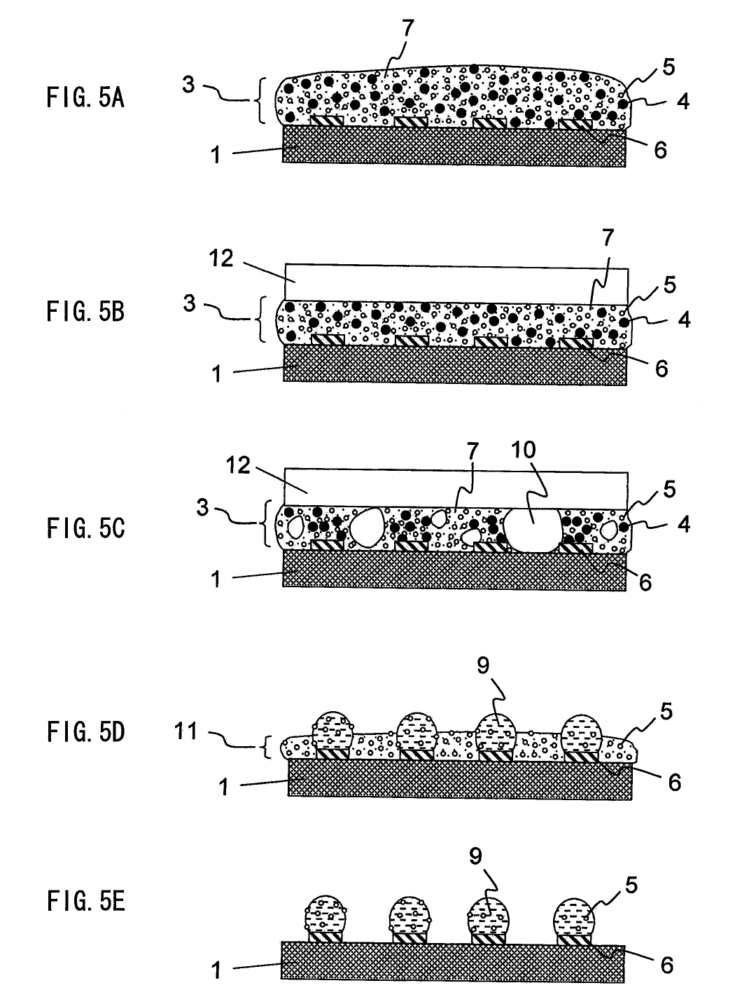

An electronic component manufacturing method wherein the air bubble generating agent is included in the solder resin mixture 3 is described referring to FIGS. 5A-5E. The air bubble generating agent (not shown) is put in the solder resin mixture 3, and the resulting solder resin mixture 3 is spread onto the electronic component 1A (see FIG. 5A). A flat plate 12 is made to abut the spread solder resin mixture 3 so that a substantially closed space is formed therebetween (see FIG. 5B), and then, the solder resin mixture 3 is heated up to a temperature higher than the temperature at which air bubbles are generated from the air bubble generating agent. Accordingly, air bubbles 10 are generated from the air bubble generating agent and grow bigger (see FIG. 5C), so that the resin 7, solder powder 4 and insulation filler 5 avoid the air bubbles 10 and thereby move to positions above the electrodes 6 to be assembled there. At the same time, the resin 7 and the solder powder 4 and the insulation filler 5 included in the resin 7 are self-assembled on the electrodes 6. Finally, the solder powder 4 wettingly spreads on the electrodes 6, and the solder bumps 9 are formed on the electrodes 6. At the time, the insulation filler 5 is also included in the solder bumps 9 (see FIG. 5D). Finally, as shown in FIG. 5E, the residual resin mixture 11 which does not constitute the solder bumps 9 is washed away, and the electronic component provided with the solder bumps can be thereby obtained.

In the case where the wettability of the melted solder powder is utilized for the self-assembly of the solder powder, solder resin mixture not including the air bubble generating agent may be used as the solder resin mixture 3. The meaning of the self-assembly of the solder powder 4 and the process of the generation of the self-assembly are as described in the preferred embodiment 1.

In the conventional mounting method wherein solder balls are mounted on the electrodes of the electronic component, it is not possible for the solder balls to include the insulation filler. In the present invention, the insulation filler 5 is included in the solder resin mixture 3 in the electronic component manufacturing method wherein the solder powder is self-assembled. As a result, the structure wherein the solder bumps 9 are formed on the electrodes 6 and the insulation filler 5 are included therein can be easily obtained.

As in the case of the preferred embodiment 1, the average particle diameter of the insulation filler 5 is preferably smaller than the average particle diameter of the solder powder 4 included in the solder resin mixture 3 because the insulation filler 5 can be thereby more easily included in the solder bumps 9. The average particle diameter of the insulation filler 5 is preferably smaller than an interval between the electrodes 6 of the electronic component 1A and the flat plate 12.

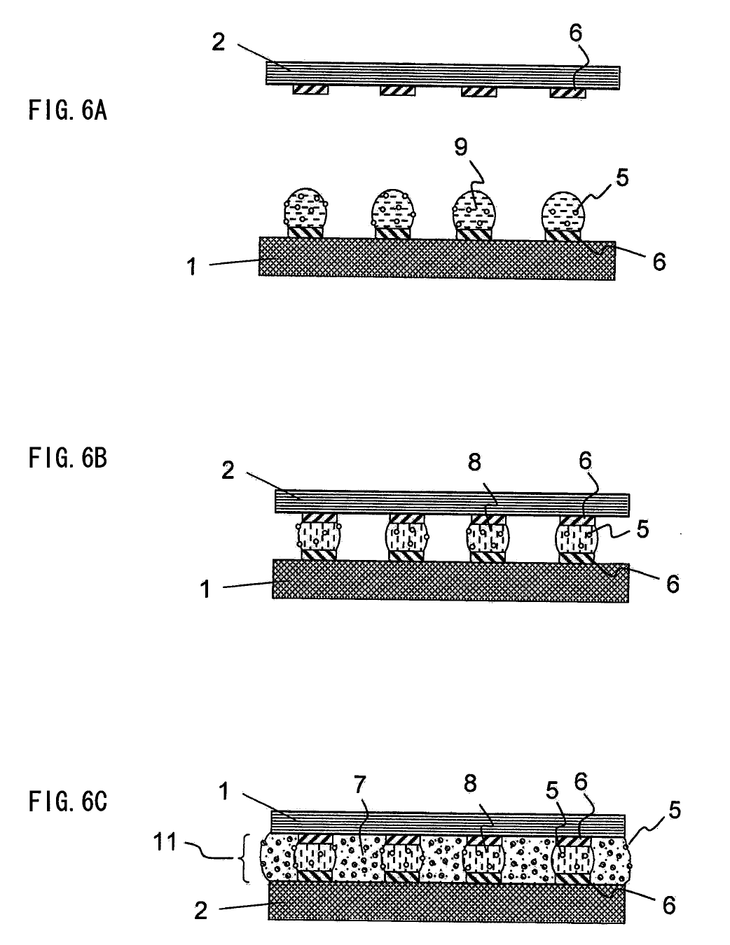

When the electronic component provided with the solder bumps thus manufactured is used, an electronic component mounted body can be manufactured according to the mounting method shown in FIGS. 6A-6C. More specifically, the electronic component 1A provided with the solder bumps (hereinafter, referred to as first electronic component 1A) and another electronic component 2 (hereinafter, referred to as second electronic component 2) are placed on one another so that the electrodes 6 (solder bumps 9) of the first electronic component 1A and electrodes 6 of the second electronic component 2 face each other (see FIG. 6A). The two electronic components 1A and 2 are heated up to a temperature at which the solder is melted or pressurized to be compressed, so that the electrodes 6 of the first electronic component 1A and electrodes 6 of the second electronic component 2 are electrically connected to each other (see FIG. 6B). Next, the resin mixture 11 including the insulation filler 5 and the resin 7 is injected into between the two components 1A and 2, and the electronic component mounted body shown in FIG. 6C can be manufactured. It is preferable to remove the oxide films of the solder bumps 9 by applying an oxide film removing agent, such as flux, to the solder-bump-9 side or the electrode-6 side of the second electronic component 2, plasma-processing the solder bumps 9, or providing other processing.

When the resin mixture 11 including the insulation filler 5 which is the same as the insulation filler 5 included in the solder bumps 9 is injected into between the two electronic components 1A and 2 in the step shown in FIG. 6C, an electronic component mounted body having the same constitution as shown in FIGS. 1C and 2D can be manufactured. When the resin mixture 11 including the insulation filler 5 which is different to the insulation filler 5 included in the solder bumps 9 is injected thereinto, an electronic component mounted body having the same constitution as shown in FIG. 3D can be manufactured.

The electronic component mounted body shown in FIG. 6C exerts an effect similar to those of the electronic component mounted bodies shown in FIGS. 1C, 2D and 3D. Thus, the electronic component mounted body improved in terms of the connection reliability can be provided.

The electronic component mounted body manufactured without the washing step after the self-assembly of the solder powder 4 may be used as it is on the condition that the resin mixture 11 including the insulation filler 5 and the resin 7 does not prevent the solder bumps 9 from being wet to form the solder connectors 8 on the electrodes 6 of the second electronic component.

The solder powder preferably does not remain in the resin mixture 11 after the self-assembly of the solder powder 4 as in the case of the preferred embodiment 1; however, a small amount of solder powder 4 may remain. In the case where the resin mixture 11 is washed off, the remaining solder powder 4 can also be removed.

The preferred embodiment 2 is preferably applicable to an electronic component such as a semiconductor, a module component, and a passive component. However, the electronic component is not particularly limited as far as it is conventionally used.

When the electronic component mounted body is manufactured using the electronic component provided with the solder bumps thus manufactured, the improvement of the connection reliability can be expected as in the case of the electronic component mounted body according to the preferred embodiment 1.

In the preferred embodiment 2, the insulation filler 5 is included in the solder bumps 9 as in the case of the preferred embodiment 1, and further, the insulation filler 5 is constituted as in the case of the preferred embodiment 1. Referring to materials of the solder powder 4, resin 7 and the like, the preferred embodiment can be realized based on materials similar to those adopted in the electronic component mounted body according to the preferred embodiment 1. The materials, therefore, are not particularly limited to those in the preferred embodiment 2 described earlier.

### Preferred Embodiment 3

In solder resin mixture according to a preferred embodiment 3 of the present invention, the solder powder and the insulation filler are scattered in the resin. The insulation filler included in the solder resin mixture is surface-processed in order to improve the wettability relative to the melted solder so that it can be easily included in the solder connecters or solder bumps when the solder powder is self-assembled.

The inclusion of the air bubble generating agent which generates air bubbles when the solder resin mixture is heated is preferably adopted. In that case, it is made easier for the solder powder to be self-assembled on the electrodes by the action of the air bubble generating agent described in the preferred embodiments 1 and 2, which makes it easier to form the solder connecters or the solder bumps including the insulation filler.

These solder resin mixtures thus described can be useful in the mounting methods described in the preferred embodiments 1 and 2.

The solder resin mixture preferably has a paste-like shape or a sheet-like shape. The paste-like mixture can be supplied to an electronic component by means of a dispenser, or a printing or transfer method. Resin which is solid at room temperature may be used, or resin cured up to the stage B and formed into the sheet-like shape can be bonded to the electronic component.

At least one or more types of inorganic filler selected from crystalline silica, melted silica, alumina, and alumina oxide preferably constitutes the insulation filler 5 according to the preferred embodiment 3. The shape of the filler, which may be a plate shape, a needle shape or a spherical shape, is not particularly limited. When the surface of the insulation filler 5 is modified as described in the preferred embodiment 1, a similar effect can be obtained.

The materials to be sued for the preferred embodiment 3 such as solder powder and resin can be the same as those described in the preferred embodiment 1, and are not particularly limited to those recited in the preferred embodiment 3.

An amount of the insulation filler to be included in the solder connecters or the solder bumps is affected by an amount of the insulation filler included in the solder resin mixture; type, surface condition, particle diameter, and wettability relative to the melted solder of the insulation filler; material variable such as type of the solder powder or resin; an amount of time necessary for the self-assembly in the mounting process; temperature profile; electrode diameter; electrode pitch; and the like. It is necessary to take these factors into consideration during the designing process.

The amount of the filler (insulation filler or the like) incorporated into the solder connecters in the respective preferred embodiments may be very small (approximately 1-100 pieces). Such a small amount is enough for the effect to be fully exerted.

### Implementation Example 1

In Implementation Example 1, the electronic component mounted body shown in FIG. 2D was manufactured according to the electronic component mounted body manufacturing method recited in the preferred embodiment 1.

A circuit substrate having the size of 10 mm×10 mm (ALIVH substrate supplied by Panasonic Electronic Devices Co., Ltd., electrode 100 μm, electrode pitch 200 μm, number of electrodes 10×10 (=100 pieces)) was prepared as the first electronic component 1, and a semiconductor TEG chip (electrode 100 μmφ, electrode pitch 200 μm, number of electrodes 10×10 (=100 pieces)) was prepared as the second electronic component 2.

25 wt % of epoxy-based resin of the bisphenol-F type (EPIKOTE 806 supplied by Japan Epoxy Resins Co., Ltd.)+an imidazole-based curing agent (supplied by SHIKOKU CHEMICALS CORPORATION) was used as the resin 7. 30 wt % of SnAgCu (particle diameter 17 μm) was used as the solder powder 4. 42 wt % of spherical silica filler (supplied by DENKI KAGAKU KOGYO KABUSHIKI KAISHA, FB-35, particle diameters 9 μm) was used as the insulation fillers 5, and 3 wt % of diethylene glycol dimethlether (supplied by Wako Pure Chemical Industries, Ltd.) was used as the air bubble generating agent. A solder resin mixture 3 in which these materials were mixed was prepared.

According to the mounting method shown in FIGS. 2A-2D, the solder resin mixture 3 was spread onto a surface of the circuit substrate, the first electronic component 1, on which electrodes are formed, and the semiconductor, which was the first electronic component 2, was mounted at a determined position on the surface of the circuit substrate provided with the electrodes so that the electrodes 6 of the circuit substrate and the electrodes 6 of the semiconductor faced with each other. Then, heat was applied thereto at 250° C. for 20 seconds, so that air bubbles were generated from the air bubble generating agent, and the solder powder 4 was self-assembled on the electrodes 6, and consequently the solder connecters 8 were formed. In the formation, the insulation filler 5 was included in the solder connecters 8. Heat was continuously applied at 250° C. so that the resin 7 was further cured. As a result, the semiconductor and the circuit substrate were fixed, and the electronic component mounted body shown in FIG. 2D was manufactured. The application of heat continued for 10 minutes in total.

### Implementation Example 2

The materials similar to those in the Implementation Example 1 were used, and the electronic component mounted body was manufactured according to the mounting method shown in FIGS. 2A-2D, wherein circuit substrates were used as both of the first electronic component 1 and second electronic component 2. The heat was applied at 240° C. for 30 seconds so that the solder powder 4 was self-assembled on the electrodes 6 and the solder connecters 8 were formed, and the insulation filler 5 was included in the solder connecters 8. The heat was further applied at 150° C. for one hour so that the resin 7 was further cured. As a result, the circuit substrates were fixed to each other, and the electronic component mounted body shown in FIG. 2D was manufactured.

### Implementation Example 3

20 wt % of silicon-based resin (methyl phenyl silicon oil, KF54 supplied by Shin-Etsu Chemical Co., Ltd.) was used as the resin 7. 30 wt % of SnAgCu (particle diameter 17 μm) was used as the solder powder 4. 45 wt % of spherical silica filler (supplied by DENKI KAGAKU KOGYO KABUSHIKI KAISHA, FB-35, particle diameter 9 μm) was used as the insulation filler 5. 5 wt % of diethylene glycol dimethlether (supplied by Wako Pure Chemical Industries, Ltd.) was used as the air bubble generating agent. A solder resin mixture 3 in which these materials were mixed was prepared. The components used in the Implementation Example 1 were used as the first electronic component 1 and the second electronic component 2. Further, a glass plate (10 mm×10 mm×1 mm, supplied by Matsunami Glass Ind., Ltd.) was prepared as the flat plate 12.

The solder resin mixture 3 was spread onto the surface of the circuit substrate on which electrodes were provided based on the mounting method shown in FIGS. 5A-5E, and the flat plate 12 was made to abut the surface provided with the electrodes. The resulting circuit substrate was heated at 240° C. for 30 seconds so that air bubbles were generated from the air bubble generating agent, and the solder powder 4 was self-assembled on the electrodes 6 so that the solder bumps 9 were formed, and the insulation filler 5 was included in the solder bumps 9 at the same time. Then, the flat plate 12 was removed, and the resin mixture 11 including the epoxy resin 7 and the insulation filler 5 was washed off with isopropyl alcohol. As a result, the electronic component provided with the solder bumps shown in FIG. 5E was manufactured.

The semiconductor used in the Implementation Example 1 was mounted on the manufactured electronic component provided with the solder bumps at a determined position thereof so that the solder bumps 9 formed on the electrodes 6 of the circuit substrate and the electrodes 6 of the semiconductor faced each other. The resulting electronic component was heated at 240° C. for three minutes, and the electronic component mounted body shown in FIG. 6B was manufactured. An under-fill agent (epoxy resin including silica filler, T639/R1000, supplied by Nagase ChemteX Corporation) was injected as the resin mixture 11 into the manufactured electronic component mounted body, which was then heated to be cured. As a result, the electronic component provided with the solder bumps shown in FIG. 6C was manufactured.

### Comparative Example 1

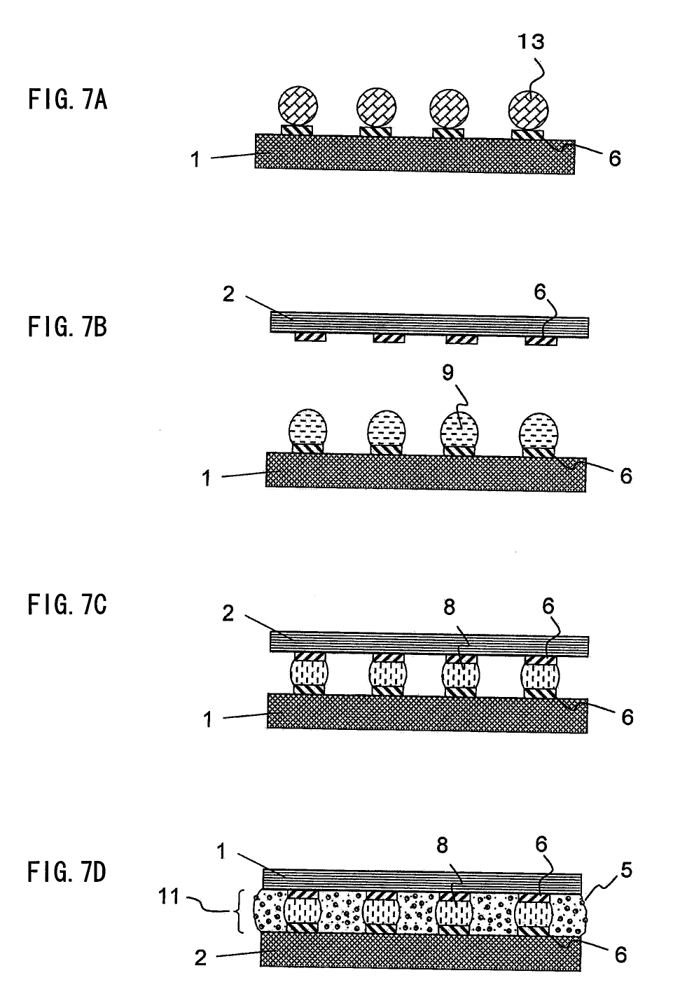

According to the mounting method shown in FIGS. 7A-7D, an electronic component mounted body was manufactured. The circuit substrate used in the Implementation Example 1 was used, and flux (supplied by Senju Metal Industry Co., Ltd., Delta Lax 523H, not shown) was applied to the electrodes 6 of the circuit substrate, and solder balls 13 (supplied by Senju Metal Industry Co., Ltd., 100 μmφ) were mounted thereon at determined positions (see FIG. 7A). The resulting circuit substrate was heated at 240° C. so that the electronic component provided with the solder bumps was manufactured. Needless to say, the solder bumps do not include the insulation filler. The semiconductor recited in the Implementation Example 1 was mounted on the electronic component provided with the solder bumps in a manner similar to the mounting method described in the Implementation Example 3. More specifically, the semiconductor was mounted on the electronic component provided with the solder bumps at a determined position thereof so that the solder bumps 9 formed on the electrodes 6 of the circuit substrate and the electrodes 6 of the semiconductor faced each other (see FIG. 7B). The resulting electronic component was heated at 240° C. for three minutes, and the electronic component mounted body shown in FIG. 7C was manufactured. The under-fill agent (epoxy resin including silica fillers, T639/R1000, supplied by Nagase ChemteX Corporation) was injected as the resin mixture 11 into the manufactured electronic component mounted body, which was then heated to be cured. As a result, the electronic component mounting body shown in FIG. 7D was manufactured.

The electronic component mounting bodies according to the Implementation Examples 1-3 and the Comparative Example 1 were subjected to a gas-phase thermal impact test (one cycle: 125° C. for 30 minutes and −40° C. for 30) to evaluate the connection reliability. Test results showed that the connection resistance did not increase in any of the electronic component mounting bodies according to the Implementation Examples 1-3 even after the 1,000-cycle or more tests were conducted, while the increase of the resistance value was observed after 700-cycle tests at some sections in the electronic component mounted body according to the Comparative Example 1, indicating the occurrence of a connection failure. In these connection-failure sections, cracks were observed in the solder connecters 8. Thus, when the insulation filler 5 is included in the solder connecters 8, the electronic component mounted body superior in its connection reliability can be provided.

### INDUSTRIAL APPLICABILITY

The electronic component mounted body, electronic component provided with solder bumps, solder resin mixture and mounting method according to the present invention are applicable to the flip-chip mounting for the next-generation LSIs, inter-substrate connection, and the like.

1. An electronic component mounted body comprising:
a first electronic component provided with a plurality of electrodes;
a second electronic component provided with a plurality of electrodes and facing the first electronic component in a state where the electrodes thereof face the electrodes of the first electronic component; and
solder connecters provided between the electrodes of the first electronic component and the electrodes of the second electronic component so as to electrically connect the electrodes of the first and second electronic component to each other, wherein
the solder connecters include insulation filler in such a way that only a part of the insulation filler is embedded therein.

2. The electronic component mounted body as claimed in claim 1, wherein the insulation filler is inorganic filler.

3. The electronic component mounted body as claimed in claim 1, wherein
a resin mixture including resin and insulation filler is provided between the first and second electronic components, and the respective electronic components are bonded by the resin mixture.

4. The electronic component mounted body as claimed in claim 3, wherein
a coefficient of thermal expansion of the insulation filler included in the solder connecters is smaller than a coefficient of thermal expansion of the resin.

5. The electronic component mounted body as claimed in claim 3, wherein
the insulation filler included in the resin mixture and the insulation filler included in the solder connecters are of the same constitution.

6. The electronic component mounted body as claimed in claim 1, wherein
at least a material selected from crystalline silica, melted silica, alumina, and alumina oxide constitutes the insulation filler.

7. The electronic component mounted body as claimed in claim 1, wherein
the first electronic component is a circuit substrate, and the second electronic component is a semiconductor.

8. The electronic component mounted body as claimed in claim 1, wherein
the first electronic component and the second electronic component are both circuit substrates.

9. The electronic component mounted body as claimed in claim 1, wherein
the solder connecters are formed when solder powder is melted, the solder connecters are formed between the electrodes of the respective electronic components when the solder powder is self-assembled, and the insulation filler in the solder connecters is included in the solder connecters when the solder powder is self-assembled.

10. The electronic component mounted body as claimed in claim 9, wherein
particle diameters of the insulation filler in the solder connecters are smaller than particle diameters of the solder powder.

11. An electronic component mounted body comprising:
a first electronic component provided with a plurality of electrodes;
a second electronic component provided with a plurality of electrodes and facing the first electronic component in a state where the electrodes thereof face the electrodes of the first electronic component;
solder connecters provided between the electrodes of the first electronic component and the electrodes of the second electronic component so as to electrically connect the electrodes of the first and second electronic component to each other; and
a resin mixture provided between the first and second electronic components so as to bond the first and second electronic components, wherein
the solder connecters and the resin mixture include insulation filler of the same constitution, and
the solder connecters include insulation filler in such a way that only a part of the insulation filler is embedded therein.

12. The electronic component mounted body as claimed in claim 11 wherein
the solder connecters are formed when solder powder is melted, the solder connecters are formed between the electrodes of the respective electronic components when the solder powder is self-assembled, and the insulation filler in the solder connecters is included in the solder connecters when the solder powder is self-assembled.

13. The electronic component mounted body as claimed in claim 12, wherein particle diameters of the insulation filler in the solder connecters are smaller than particle diameters of the solder powder.

14. An electronic component provided with solder bumps comprising:
a plurality of electrodes; and
solder bumps provided on the electrodes, wherein
the solder bumps include insulation filler in such a way that only a part of the insulation filler is embedded therein.

15. The electronic component provided with solder bumps as claimed in claim 14, wherein
at least a material selected from crystalline silica, melted silica, alumina, and alumina oxide constitutes the insulation filler.

16. The electronic component provided with solder bumps as claimed in claim 14, wherein
the electronic component is a semiconductor.

17. The electronic component provided with solder bumps as claimed in claim 14, wherein
the electronic component is a circuit substrate.

18. The electronic component provided with solder bumps as claimed in claim 14, wherein
the solder bumps are formed when solder powder is melted, the solder bumps are formed on the electrodes when the solder powder is self-assembled, and the insulation filler in the solder connecters is included in the solder bumps when the solder powder is self-assembled.

19-21. (canceled)

22. A method of mounting an electronic component wherein a first electronic component provided with a plurality of electrodes and a second electronic component provided with a plurality of electrodes are placed so that the electrodes of the respective electronic components face each other, and the electrodes of the first and second electronic components facing each other are electrically connected to each other via solder, including:
a first step in which a solder resin mixture including resin, solder powder, insulation filler and an air bubble generating agent is supplied to a surface of the first electronic component on which the electrodes are formed;
a second step in which the second electronic component is placed so as to face the first electronic component in the state where the electrodes of the respective electronic components face each other;
a third step in which the solder resin mixture is heated; and
a fourth step in which solder connecters are formed when air bubbles are generated from the air bubble generating agent and the solder powder included in the solder resin mixture is thereby self-assembled on the electrodes of the first and second electronic components, so that the electrodes of the respective electronic components are electrically connected to each other, wherein
at least a part of the insulation filler is included in the solder connecters when the solder powder is self-assembled in the fourth step.

23. The method of mounting an electronic component as claimed in claim 22, further including a fifth step in which the resin in the solder resin mixture is solidified so that the first and second electronic components are bonded after the fourth step.

24. (canceled)

25. The method of mounting electronic components as claimed in claim 22, wherein
the second electronic component is a semiconductor.

26. A method of manufacturing an electronic component wherein solder bumps are formed on a plurality of electrodes provided therein, including:
a first step in which a solder resin mixture including resin, solder powder and insulation filler and an air bubble generating agent is supplied to the electronic component; and
a second step in which the solder resin mixture is heated;
a third step in which the solder bumps are formed on the electrodes when air bubbles are generated from the air bubble generating agent and the solder powder included in the solder resin mixture is thereby self-assembled, wherein
at least a part of the insulation filler is included in the solder connecters when the solder powder is self-assembled in the third step.

27. (canceled)
